(19) United States
(12) Patent Application Publication
(10) Pub. No.: US 2026/0304820 A1
(43) Pub. Date: Oct. 1, 2026

(54) DEVICE INCLUDING TWO DIMENSIONAL JUNCTION BETWEEN VAN DER WAALS MATERIAL AND ELECTRODE, AND MANUFACTURING METHOD THEREOF

(71) Applicant: POSTECH RESEARCH AND BUSINESS DEVELOPMENT FOUNDATION, Pohang-si (KR)

(72) Inventors: Gilho LEE, Pohang-si (KR); Seong JANG, Pohang-si (KR)

(73) Assignee: POSTECH RESEARCH AND BUSINESS DEVELOPMENT FOUNDATION, Pohang-si (KR)

(21) Appl. No.: 19/402,345

(22) Filed: Nov. 26, 2025

(30) Foreign Application Priority Data
Mar. 28, 2025 (KR) 10-2025-0040225

(51) Int. Cl. H10D 30/47; H10D 30/01

(52) U.S. Cl. CPC H10D 30/481; H10D 30/017

(57) ABSTRACT

Disclosed are a device including a two-dimensional junction between a van der Waals material and an electrode, and a manufacturing method thereof, the device including: a lower insulating layer made of an insulating 2D material; a conductive layer stacked on the lower insulating layer by interlayer van der Waals bonding and made of a conductive 2D material; an upper insulating layer stacked on the conductive layer by interlayer van der Waals bonding, made of an insulating 2D material, and having a selective etching region formed therein; an electrode layer formed in the selective etching region to form a planar contact with the conductive layer; a gate insulating layer formed on the upper insulating layer and the electrode layer; and first and second gate electrodes located on the gate insulating layer, under the lower insulating layer, or both, and applying a gate electric field to at least a partial region of the conductive layer.

### CROSS-REFERENCE TO RELATED APPLICATIONS

This application claims the benefit of and priority to Korean Patent Application No. 10-2025-0040225, filed on Mar. 28, 2025, the entire contents of which are incorporated herein by reference for all purposes.

### TECHNICAL FIELD

The present invention relates to a device including a two-dimensional junction (2D junction) between a van der Waals material and an electrode and a manufacturing method thereof, and more particularly, to a device including a 2D junction between a van der Waals material having high charge transport transparency and an electrode, and a manufacturing method thereof.

This application claims the benefit of and priority to Korean Patent Application No. 10-2025-0040225, filed on Mar. 28, 2025, the entire contents of which are incorporated herein by reference for all purposes.

### BACKGROUND ART

Graphene has high electron mobility, electrically bipolar characteristics, and can control charge density according to gate voltage, so it is utilized in various electronic device and quantum device applications. To secure the performance of such graphene-based devices, it is very important to minimize the contact resistance between the metal electrode and graphene.

In early graphene devices, a so-called 2D planar contact method, in which a metal is directly deposited on the upper surface of graphene to make contact, was widely used. However, this method had a problem that polymer residues, plasma damage, surface contamination, etc. intervene between the metal and graphene, lowering the cleanliness of the contact interface, thereby increasing contact resistance. In addition, the lower part of the graphene was unintentionally doped due to the work function difference between the metal and the graphene, an imbalance occurred in the doping state between the channel region and the junction region, and charge transfer characteristics were degraded.

A technology developed to solve these problems is the 1D edge contact method (see Wang et al., “One-Dimensional Electrical Contact to a Two-Dimensional Material”, Science 342, 614-617 (2013)). This method has a structure in which graphene is encapsulated from the top and bottom with hexagonal boron nitride (hBN), and then the side (edge) of the graphene is exposed through selective etching, and metal is deposited on the edge portion to form an electrical contact. This structure is the method with the highest transparency of the electrode-graphene junction known to date, and has the advantage that the direct contact surface between graphene and metal is limited to the atomic level, so there is little interface contamination and very low contact resistance can be realized.

FIG. 1 is a schematic diagram showing the structure of a device according to the prior art of a ID edge contact method between a van der Waals material and an electrode. Referring to FIG. 1, in the device according to the prior art of the 1D edge contact method, graphene 1 is encapsulated with hexagonal boron nitride 2 and 3, a contact is made between the edge portion of the graphene 1 and the metal 4, and the charge density and polarity of the channel region (n_{ch}) of the graphene are controlled by electric field application through a back gate electrode 6 located under a substrate 5.

However, this 1D edge contact method structurally has the following problems. First, the work function difference between the metal and graphene still exists, and the junction region of the graphene is mainly n-doped by the metal. Due to this, when the channel region is set to p-type, a PN junction is formed between the junction region and the channel region, and electron transport transparency is significantly degraded. This leads to an increase in junction resistance, acting as a barrier hindering current flow, and unnecessary energy consumption of the device increases. Second, such a barrier is further intensified especially when entering a quantum Hall regime under a high magnetic field, and an insulating state where the filling factor is close to 0 occurs at the junction region, hindering device operation. Third, when a superconducting electrode is used, the doping barrier formed at the junction region prevents the effective transfer of the superconducting proximity effect, and consequently places great restrictions on the implementation of Josephson junctions or Andreev reflections.

In conclusion, the existing 2D planar contact method has a simple structure but low contact transparency due to contamination problems, and the 1D edge contact method solved the contamination problem but still had limitations in doping asymmetry and application range. Therefore, for high performance of graphene devices, a structure capable of actively controlling the graphene doping state of the junction region by an external electrical signal while securing the cleanliness of the contact interface with the electrode is required.

### PRIOR ART DOCUMENTS

### Non-Patent Literature

(Non-Patent Literature 1) Wang et al., “One-Dimensional Electrical Contact to a Two-Dimensional Material”, Science 342, 614-617 (2013)

### SUMMARY OF THE INVENTION

### Technical Problem

The present invention is intended to solve the problems of the prior art described above, and one of the various objects of the present invention is to provide a device including a 2D junction between a van der Waals material and an electrode, which has excellent charge transport characteristics and stable electrical characteristics of the contact interface by minimizing physical damage occurring during an etching process, and a manufacturing method thereof.

Another object is to provide a device and a manufacturing method thereof capable of stably implementing physical phenomena such as superconducting proximity effect, Josephson coupling, and Andreev reflection even under bipolar doping conditions when a superconductor is used as an electrode.

Furthermore, an object is to provide a device structure capable of observing and utilizing quantum phenomena such as Crossed Andreev Conversion by dramatically lowering contact resistance even in a high magnetic field quantum Hall state, particularly in a negative filling factor region.

### Technical Solution

According to an aspect, there is provided a device including a two-dimensional junction between a van der Waals material and an electrode, the device comprising: a lower insulating layer made of an insulating 2D material; a conductive layer stacked on the lower insulating layer by interlayer van der Waals bonding and made of a conductive 2D material; an upper insulating layer stacked on the conductive layer by interlayer van der Waals bonding, made of an insulating 2D material, and having a selective etching region formed therein; an electrode layer formed in the selective etching region to form a planar contact with the conductive layer; a gate insulating layer formed on the upper insulating layer and the electrode layer; and first and second gate electrodes located on the gate insulating layer, under the lower insulating layer, or both, and applying a gate electric field to at least a partial region of the conductive layer.

In an embodiment, the conductive layer may include a junction region forming a planar contact with the electrode layer and a channel region encapsulated by the upper insulating layer and the lower insulating layer, wherein charge density and polarity of the junction region are controlled by electric field application through the first gate electrode, and charge density and polarity of the channel region are controlled by electric field application through the first and second gate electrodes.

In an embodiment, the first gate electrode may be located under the lower insulating layer, the second gate electrode may be located on the electrode layer, and the gate insulating layer may be interposed between the electrode layer and the second gate electrode.

In an embodiment, the electrode layer may include one or more superconductors selected from the group consisting of niobium (Nb), niobium nitride (NbN), titanium (Ti), niobium titanium nitride (NbTiN), molybdenum rhenium alloy (MoRe), tantalum (Ta), aluminum (Al), vanadium (V), lead (Pb), and indium (In).

In an embodiment, the device may be any one of a semiconductor device, a superconducting qubit, a quantum Hall device, and a superconducting Josephson junction device. In an embodiment, the device is a quantum Hall device, and in a state where a filling factor of the channel region, which is the conductive layer, is controlled to be a negative value (v<0) through the first and second gate electrodes, Crossed Andreev Conversion occurs at an interface between the electrode layer and the channel region to exhibit a negative downstream resistance.

In an embodiment, a surface of the conductive layer corresponding to the selective etching region is p-doped by fluorine (F) atoms, and the p-type doping compensates for n-type doping induced by contact with the electrode layer, thereby reducing a work function difference (ΔW) between the conductive layer and the electrode layer.

In an embodiment, when a charge density (n_{co}) of the junction region controlled by the first gate electrode is matched to have the same polarity as a charge density (n_{ch}) of the channel region, a potential barrier strength (Z) at an interface between the junction region and the channel region may be 0.3 or less based on a Blonder-Tinkham-Klapwijk (BTK) model.

According to another aspect, there is provided a method of manufacturing a device including a two-dimensional junction between a van der Waals material and an electrode, the method comprising: sequentially stacking a lower insulating layer made of an insulating 2D material, a conductive layer made of a conductive 2D material, and an upper insulating layer made of an insulating 2D material, such that the lower insulating layer, the conductive layer, and the upper insulating layer are interlayer-bonded by van der Waals force; forming a selective etching region in the upper insulating layer to expose a part of the conductive layer; forming an electrode layer to form a planar contact with the exposed conductive layer; forming a gate insulating layer on the upper insulating layer and the electrode layer; and forming first and second gate electrodes on the gate insulating layer, under the lower insulating layer, or both to apply a gate electric field to at least a partial region of the conductive layer.

In an embodiment, the conductive layer may include a junction region forming a planar contact with the electrode layer and a channel region encapsulated by the upper insulating layer and the lower insulating layer, wherein charge density and polarity of the junction region are controlled by electric field application through the first gate electrode, and charge density and polarity of the channel region are controlled by electric field application through the first and second gate electrodes.

In an embodiment, the first gate electrode may be formed under the lower insulating layer, and the second gate electrode may be formed on the gate insulating layer.

In an embodiment, in the step of forming the selective etching region, a fluorine-based gas plasma may be applied under conditions of a pressure of 150 mTorr to 500 mTorr and an RF power of 30 W or less.

In an embodiment, the fluorine-based gas may include carbon tetrafluoride (CF₄), the pressure may be 200 mTorr to 300 mTorr, and the RF power may be 5 W to 15 W.

In an embodiment, the step of forming the selective etching region may include a step in which fluorine (F) atoms derived from an etching gas remain on a surface of the exposed conductive layer to induce p-type doping, thereby compensating for n-type doping occurring during formation of the electrode layer to reduce a work function difference between the conductive layer and the electrode layer.

In an embodiment, the step of forming the electrode layer may control interface characteristics between a metal and the conductive layer such that a potential barrier parameter (Z) at an interface with the conductive layer is 0.3 or less, thereby allowing the completed device to exhibit Crossed Andreev Conversion characteristics in a negative filling factor region.

### Advantageous Effects

The device and the manufacturing method thereof according to the present invention have the following effects.
(1) By encapsulating the conductive 2D material based on van der Waals bonding, contamination and surface damage due to external processes can be prevented and cleanliness of the contact interface can be secured.
(2) In performing selective etching on the upper insulating layer, by inducing isotropic chemical reaction rather than anisotropic physical bombardment using high-pressure fluorine-based plasma, damage to the atomic structure of the surface of the conductive layer can be prevented. Through this, by forming a 2D planar contact between the conductive layer and the electrode, the contamination problem of the conventional 2D planar contact structure can be solved, and while structural simplicity and process ease are superior to the ID edge contact structure, equivalent or better contact transparency can be implemented.
(3) By individually applying an electric field to each of the junction region and the channel region in the conductive layer using two gate electrodes, the charge density and polarity state can be independently controlled, and the formation of a PN junction barrier can be suppressed. In particular, by matching the polarities of the junction region and the channel region, the formation of a PN junction barrier is suppressed, and the potential barrier strength (Z) based on the BTK (Blonder-Tinkham-Klapwijk) model can be lowered to 0.3 or less to realize an ideal transparent junction.
(4) Fluorine (F) atoms derived from the selective etching process remain on the surface of the conductive layer to induce p-type doping, and this electrically compensates for n-type doping occurring upon contact with the electrode metal, thereby having the effect of reducing the work function difference between the electrode and the conductive layer and improving contact resistance.
(5) In the case of using a superconductor as an electrode, various quantum electronic effects such as Andreev reflection, Josephson coupling, T-junction state control, and Crossed Andreev Conversion can be implemented even under bipolar doping conditions. In particular, even in the negative filling factor (v<0) region of the quantum Hall effect, high contact transparency is maintained, so that negative downstream resistance characteristics due to Crossed Andreev Conversion can be stably implemented.
(6) It can be utilized as a base technology applicable to high-functional application devices such as Josephson junction devices, superconducting qubits, and quantum Hall devices as well as semiconductor devices.

The effects of the present invention are not limited to the above-described effect and should be understood to include all effects that can be inferred from the configuration described in the detailed description or claims of the present specification.

### [BRIEF DESCRIPTION OF THE DRAWINGS]

FIG. 1 is a schematic diagram showing the structure of a device according to the prior art of a 1D edge contact method between a van der Waals material and an electrode.

FIG. 2 is a view showing the basic structure of a device including a 2D junction between a van der Waals material and an electrode according to an embodiment of the present invention.

FIG. 3 shows the configuration of a quantum Hall superconducting hybrid device implemented using a device according to an embodiment of the present invention.

FIG. 4 shows a graphene Josephson junction device constructed based on a device according to an embodiment of the present invention.

FIGS. 5(a) and 5(b) schematically show changes in energy bands in the conductive layer in the devices of FIG. 1 and FIG. 2, respectively.

FIGS. 6 to 9 are views sequentially showing a manufacturing process of a device according to an embodiment of the present invention.

FIG. 10 is a graph showing conductance characteristics according to gate voltage of a device according to an embodiment of the present invention.

FIG. 11 is a graph showing a correlation between a contact barrier parameter (Z) and transparency (t) in a device according to an embodiment of the present invention.

FIG. 12 is a graph showing negative downstream resistance characteristics exhibited by a device according to an embodiment of the present invention in a quantum Hall state (v=−2).

FIG. 13 is a graph comparing width-normalized critical currents (I_{C}/W) of an embodiment of the present invention (2D contact) and the prior art (1D contact).

### DETAILED DESCRIPTION OF EXAMPLE EMBODIMENTS

Hereinafter, an aspect of the present invention will be described with reference to the accompanying drawings. However, the descriptions of the present specification may be implemented in various different forms, and thus are not limited to the embodiments described herein. In order to clearly explain an aspect of the present invention in the drawings, parts irrelevant to the description are omitted, and similar reference numerals are attached to similar parts throughout the specification.

Throughout the specification, when a component (or region, layer, part, etc.) is referred to as being “on”, “connected to”, or “coupled to” another component, it means that it may be directly disposed/connected/coupled on the other component or a third component may be disposed therebetween.

Throughout the specification, when a part “includes” a component, it means that it may further include other components, not excluding other components, unless specifically stated to the contrary.

Throughout the specification, terms such as “on”, “upper”, “under”, and “lower” are used to describe the relationship of components shown in the drawings. The terms are relative concepts and are described based on the directions indicated in the drawings.

Terms including ordinal numbers such as ‘first’ or ‘second’ used in the present specification may be used to describe various components or steps, but the components or steps should not be limited by the ordinal numbers. Terms including ordinal numbers should be interpreted only for the purpose of distinguishing one component or step from other components or steps.

Unless defined otherwise, all terms (including technical and scientific terms) used herein have the same meaning as commonly understood by one of ordinary skill in the art to which the present invention belongs. In addition, terms such as those defined in commonly used dictionaries should be interpreted as having meanings consistent with the meanings in the context of the related art, and should not be interpreted in an overly ideal or overly formal sense unless explicitly defined herein.

### Device Including Two-Dimensional Junction between van der Waals Material and Electrode

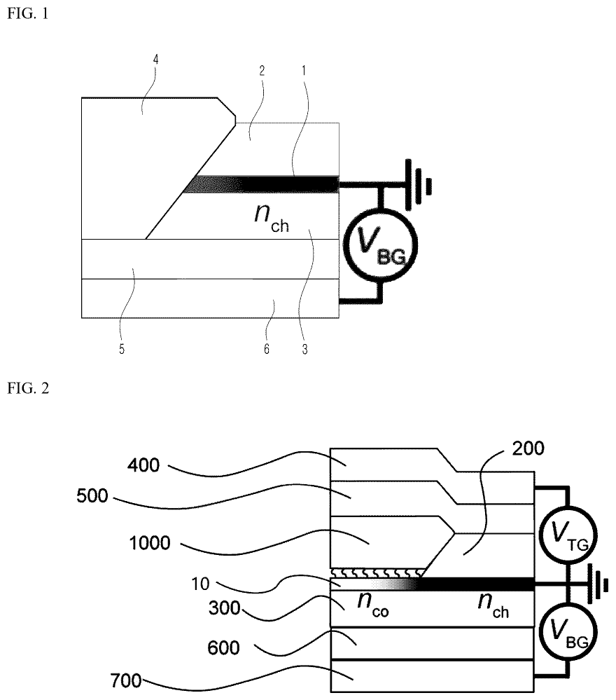

FIG. 2 is a view showing the basic structure of a device including a 2D junction between a van der Waals material and an electrode according to an embodiment of the present invention.

Referring to FIG. 2, the device may include a conductive layer 10, an upper insulating layer 200, a lower insulating layer 300, an electrode layer 1000, a gate insulating layer 500, a first gate electrode 700, and a second gate electrode 400.

The conductive layer 10 may be formed of a 2D material having electrical conductivity, such as graphene. The conductive layer 10 is disposed between the lower insulating layer 300 and the upper insulating layer 200 formed of a 2D material having electrical insulation, and is interlayer-bonded and encapsulated by van der Waals force. By forming such a stacked structure, the conductive layer 10 can be protected from contamination or damage during an external process.

The thickness of the lower insulating layer 300 and the upper insulating layer 200 may be 10 to 30 nm, but is not limited thereto.

The conductive 2D material constituting the conductive layer 10 may be at least one selected from the group consisting of Graphene, Arsenic Telluride, Bismuth Sulfide, Bismuth Antimony Selenide Telluride, Bismuth Antimony Telluride Selenide, Bismuth Selenide, Bismuth Selenide Telluride, Bismuth Telluride Iodide, Bismuth Telluride, Bismuth Strontium Calcium Copper Oxide, Cobalt Tantalum Sulfide, Chromium Bromide, Chromium Telluride, Iron Germanium Telluride, Iron Selenide Telluride, Iron Selenide, Hafnium Telluride, Lanthanum Telluride, Molybdenum Telluride, Niobium Selenide, Niobium Sulfide, Niobium Telluride, Nickel Telluride, Black Phosphorus, Palladium Telluride, Platinum Telluride, Tantalum Sulfide, Tantalum Iron Sulfide, Tantalum Iridium Telluride, Tantalum Telluride, Tantalum Nickel Selenide, Titanium Telluride, Vanadium Selenide, Vanadium Telluride, and Zirconium Telluride, and may be, for example, single layer graphene or few layer graphene, but is not limited thereto.

The insulating 2D materials constituting the upper insulating layer 200 and the lower insulating layer 300 may be the same as or different from each other, and may be at least one selected from the group consisting of Boron Nitride, Cobalt Phosphorus Sulfide, Chromium Chloride, Chromium Germanium Telluride, Chromium Iodide, Chromium Phosphorus Sulfide, Iron Chloride, Iron Phosphorus Sulfide, Iron Phosphorus Selenide, Mica, Manganese Phosphorus Sulfide, Nickel Iodide, Nickel Phosphorus Sulfide, Lead Tin Iron Antimony Sulfide, Ruthenium Chloride, and Zinc Phosphorus Sulfide, and may be, for example, hexagonal boron nitride (hBN) which has a structure similar to graphite and has excellent electrical insulation, but is not limited thereto.

The electrode layer 1000 is formed to make a planar contact with the conductive layer 10 exposed through the selective etching region formed in the upper insulating layer 200, and serves to inject or extract charge carriers (electrons or holes) through a region of the conductive layer 10 making a planar contact with the electrode layer 1000 (hereinafter referred to as “junction region, n_{co}”) to other regions (hereinafter referred to as “channel region, n_{ch}”). At this time, the selective etching region is formed through isotropic dry etching under a high pressure (e.g., 150 mTorr or more) condition, so that physical damage to the surface of the exposed conductive layer 10 is suppressed and a doping compensation effect due to residual fluorine (F) atoms can be obtained.

The electrode layer 1000 may be formed of a general metal (e.g., Ti, Au, etc.) depending on the type of application device, or may be formed of a superconductor (e.g., Nb, NbN, MoRe, etc.) as described later, but is not limited thereto.

The first gate electrode 700 and the second gate electrode 400 enable independent electric field application to the junction region (n_{co}) and the channel region (n_{ch}), respectively, thereby allowing precise control of the charge density and polarity of each region.

The first gate electrode 700 and the second gate electrode 400 may be located on the gate insulating layer 500, under the lower insulating layer 300, or both, and for example, as shown in FIG. 2, the first gate electrode 700 may be located under the lower insulating layer 300, and the second gate electrode 400 may be located on the gate insulating layer 500. However, the first gate electrode 700 and the second gate electrode 400 do not necessarily have to be formed at different positions, and may be formed on the same plane but separated from each other to allow independent electric field application.

The gate insulating layer 500 is formed on the upper insulating layer 200 and the electrode layer 1000, and the gate insulating layer 500 serves to secure electrical insulation between the electrode layer 1000 and the second gate electrode 400.

The gate insulating layer 500 may include aluminum (III) oxide (Al₂O₃), but is not limited thereto.

The substrate 600 is a support layer for supporting the device, and may be, for example, a silicon substrate, a sapphire substrate, a glass substrate, a SiC substrate, a Ga₂O₃ substrate, or a diamond substrate, but is not limited thereto. The first gate electrode 700 may be separately formed inside or under the substrate 600, but if the substrate 600 is a highly doped silicon substrate, the substrate itself may serve as the first gate electrode 700.

Referring to FIG. 2, the charge density and polarity of the junction region (n_{co}) of the conductive layer 10 are controlled through a back gate voltage (V_{BG}) of the first gate electrode 700, and the charge density and polarity of the channel region (n_{ch}) may be controlled through the back gate voltage (V_{BG}) of the first gate electrode 700 and a top gate voltage (V_{TG}) of the second gate electrode 400. Through this, the charge density and polarity of the junction region (n_{co}) and the channel region (n_{ch}) can be controlled respectively, and by making the charge density and polarity of the two regions (n_{co}, n_{ch}) match, the potential barrier between the two regions (n_{co}, n_{ch}) can be minimized, and the electron transport transparency of the electrode junction can be improved.

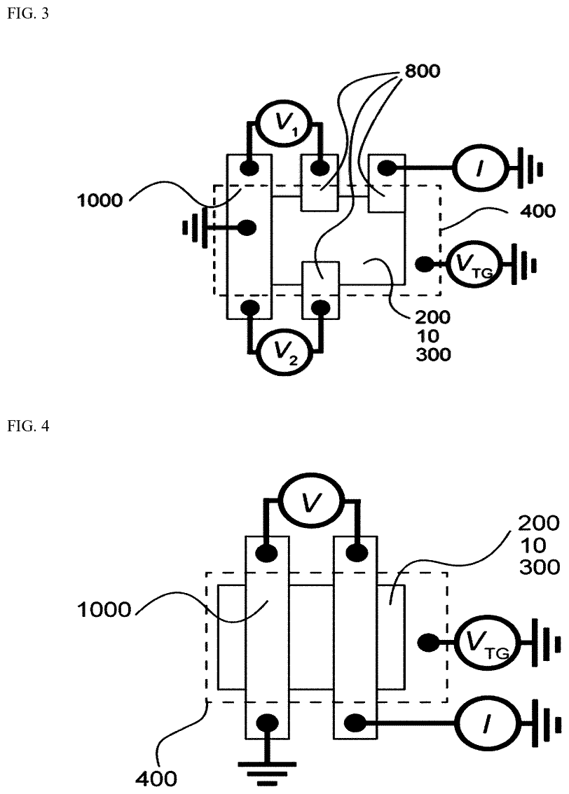

FIG. 3 shows the configuration of a quantum Hall superconducting hybrid device implemented using a device according to an embodiment of the present invention. When the graphene channel enters a quantum Hall state under a high magnetic field environment, the 2D planar contact structure of the present invention electrically aligns the polarity of the junction region graphene, thereby enabling stable coupling with the superconducting electrode without loss of contact transparency. When the current (I) flowing along the quantum Hall edge state reaches the superconducting electrode 1000, it is converted into holes through Crossed Andreev Conversion and propagates to the downstream channel, and the movement of these holes can be detected as a negative voltage signal, that is, negative downstream resistance, at the V1 or V2 electrode.

Although it is generally known that such a structure is possible only in an n-doped state, the structure of the present invention can maintain the same contact transparency and Andreev reflection characteristics in both bipolar doping conditions. In particular, it was confirmed that negative downstream resistance due to Crossed Andreev Conversion is stably detected even when the doping polarity of the junction region is set to p-type through the first gate electrode 700 and the channel region is also aligned to the same p-type through the first and second gate electrodes 700 and 400 to have a negative filling factor (v<0, for example v=−2).

This is a phenomenon that was impossible to implement in the conventional 1D contact structure, and provides a very important technical advantage in the implementation of quantum Hall-superconducting devices in that the contact doping alignment function provided by the 2D planar contact structure based on two gate electrodes (hereinafter referred to as “dual gate”) of the present invention and the formation of a transparent graphene-superconductor junction based thereon are possible.

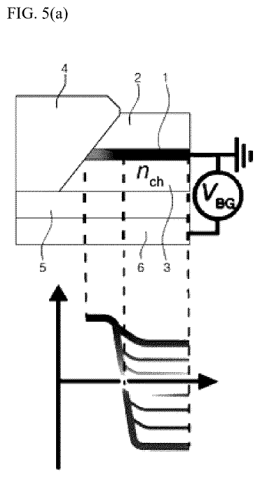

FIG. 4 shows a graphene Josephson junction device constructed based on a device according to an embodiment of the present invention. Superconducting electrodes 1000 are formed on both sides of the graphene channel 10 in a 2D planar contact manner, and the charge density and doping polarity of each of the channel and the junction region are precisely controlled through the first gate electrode 700 and the second gate electrode 400. When voltage (V) is measured while applying current (I), critical current (Ic) which is a Josephson junction characteristic, and superconducting-normal transition characteristics can be confirmed. When the current is below Ic, no voltage is applied across the junction, and when it exceeds Ic, a voltage appears and transitions to a normal state. Through this, the magnitude of Ic, gate voltage dependence, and the effect of the dual gate structure on the junction characteristics can be quantitatively evaluated.

In particular, it was confirmed that the device of the present invention exhibits a distinct Multiple Andreev Reflections (MAR) phenomenon and a high IcRn product value, indicating that the quality of the junction interface is very excellent. In addition, based on the structural feature that doping alignment is possible, a stable supercurrent can be maintained along with high contact transparency even in a p-type doping state. This is a performance region that could not be reached with the existing 1D contact structure, and drastically expands the implementation and operation range of bipolar Josephson junction devices. In addition, since Ic can be precisely controlled through gate voltage adjustment, application to quantum information devices such as gate-controlled superconducting qubits (gatemons) is also possible, and it can be utilized as a core element technology for the practical use of graphene-based quantum electronics.

Specifically comparing this, the prior art FIG. 1 shows a 1D edge contact structure. In this case, metal contacts the side (edge) of graphene, and the graphene junction region is forcibly n-doped by the work function of the metal. On the other hand, FIG. 2 of the present invention shows a 2D planar contact structure, in which a portion of the graphene surface is exposed by selectively etching the upper insulating layer 200, and metal is deposited on the corresponding portion.

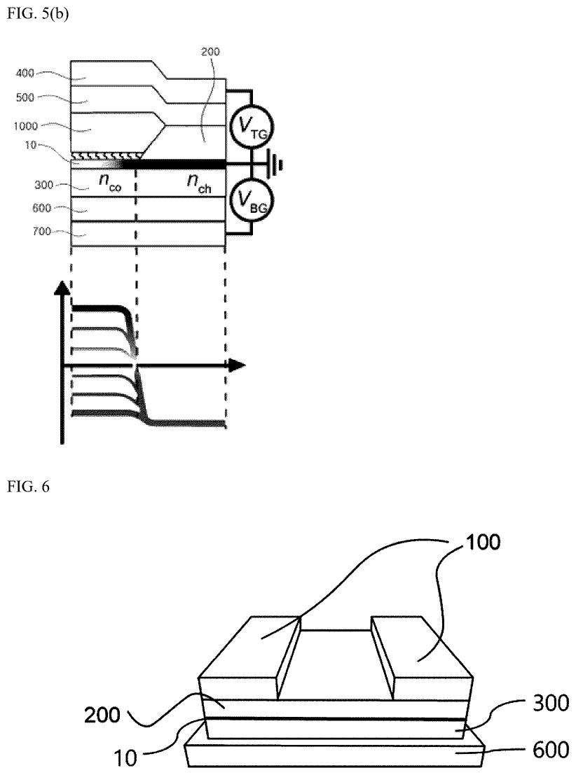

FIGS. 5(a) and 5(b) schematically show changes in energy bands in the conductive layer in the devices of FIG. 1 (prior art) and FIG. 2 (present invention), respectively.

Referring to FIG. 5(a), in the conventional 1D contact structure, the Fermi level of the junction region is pinned by the metal electrode, so the doping state cannot be controlled. Accordingly, when the channel region and the junction region have different polarity states (e.g., n-p junction), a PN junction barrier is inevitably formed, hindering charge flow.

On the other hand, referring to FIG. 5(b), in the dual gate structure of the present invention, the charge density of the junction region (n_{co}) can be independently controlled through the first gate electrode 700, and the charge density of the channel region (n_{ch}) can be controlled through the first and second gate electrodes 700 and 400. Through this, the Fermi level (EF) of the junction region can be matched with the channel region, so that a transparent junction with the potential barrier removed can be formed.

Furthermore, the fluorine-based plasma etching performed in the manufacturing process of the present invention leaves fluorine (F) atoms on the surface of the conductive layer to induce p-type doping. This serves to electrically compensate for n-type doping occurring during metal electrode contact, effectively reducing the work function difference (ΔW) between the electrode and the conductive layer to a very low level of about 50 meV or less and minimizing contact resistance.

This doping control function is not limited to superconducting electrodes, but can be equally applied when general metal electrodes (e.g., Ti, Au, Cr, etc.) are used. In fact, unintentional doping due to work function differences may occur even between general metal materials and conductive 2D materials, and the structure of the present invention provides an effective means to electrically solve this problem.

Therefore, the present invention fundamentally solved problems such as doping asymmetry, increased contact resistance, and junction barriers appearing in existing 1D edge contact structures by combining a dual gate with a 2D contact structure of an electrode and a conductive 2D material in a van der Waals stacked structure based device.

Through this, negative downstream resistance due to Crossed Andreev Conversion can be implemented even in a negative filling factor (v<0) region in a quantum Hall device, and a high critical current-normal resistance product (IcRn) with distinct multiple Andreev reflections can be achieved in a superconducting Josephson junction device.

In conclusion, the present invention provides a basis for realizing stable operation and performance improvement of next-generation quantum devices such as superconducting qubits, quantum Hall devices, and superconducting Josephson junction devices.

### Manufacturing Method of Device Including Two-Dimensional Junction between van der Waals Material and Electrode

FIGS. 6 to 9 are views sequentially showing a manufacturing process of a device according to an embodiment of the present invention.

First, after preparing a substrate 600, a lower insulating layer 300 made of an insulating 2D material, a conductive layer 10 made of a conductive 2D material, and an upper insulating layer 200 made of an insulating 2D material are sequentially stacked on the substrate 600 to encapsulate the conductive layer 10 entirely.

At this time, the substrate 600 may be, for example, a highly doped silicon (Si) wafer having an oxide film (SiO₂) with a thickness of about 300 nm formed on the surface, and in this case, the doped silicon substrate itself may perform the role of a first gate electrode 700 to be described later. In addition, the upper and lower insulating layers 200 and 300 may be hexagonal boron nitride (hBN), and the conductive layer 10 may be graphene.

Stacking may be performed by a wet transfer or dry transfer method, and is performed in a form of interlayer bonding by van der Waals force. Through this, the conductive 2D material constituting the conductive layer 10 is protected from external contamination.

Next, a selective etching region is formed in the upper insulating layer 200 to expose a part of the conductive layer 10.

Referring to FIG. 6, a mask pattern may be formed through development after depositing a mask material 100 on the upper insulating layer 200. Photoresist, electron beam resist, silicon dioxide (SiO₂), etc. may be selected as the mask material 100. A mask pattern may be formed through photolithography, electron beam lithography, etc. depending on the type of the mask material 100.

Referring to FIG. 7, a region (selective etching region) not protected by the mask material 100 among the upper insulating layer 200 may be etched through an etching process to form a selective etching region.

The etching gas may be a fluorine-based gas, preferably carbon tetrafluoride (CF₄). The reason for using CF₄ as the etching gas is that the insulating 2D material (e.g., hBN) constituting the upper insulating layer 200 is etched, whereas the conductive 2D material (e.g., graphene) constituting the conductive layer 10 is not etched. Of course, other fluorinated gases (fluorine-based gases) such as XeF₄ and HF may be used instead of CF₄ if the same purpose can be achieved.

Etching may be performed in a plasma state after supplying energy to the etching gas to form a plasma state. At this time, the etching process is preferably performed under conditions where isotropic chemical reaction is dominant rather than anisotropic physical bombardment in order to minimize physical damage to the surface of the conductive layer 10.

To this end, in an embodiment of the present invention, plasma etching is performed in a high pressure range of about 150 mTorr to about 500 mTorr, preferably about 200 mTorr to about 300 mTorr, and a low RF power range of about 30 W or less, preferably about 5 W to about 15 W. Such mild plasma conditions may be advantageous for selectively removing only the upper insulating layer 200 while preserving the atomic structure of the lower conductive layer 10 intact.

In addition, in this process, fluorine (F) atoms derived from the etching gas may remain minutely on the surface of the exposed conductive layer 10 to induce p-type doping (hole-doping), which serves to compensate for the work function difference occurring during subsequent electrode formation.

The conductive layer 10 acts as an etching stop layer to prevent etching of the lower insulating layer 300 located under the conductive layer 10.

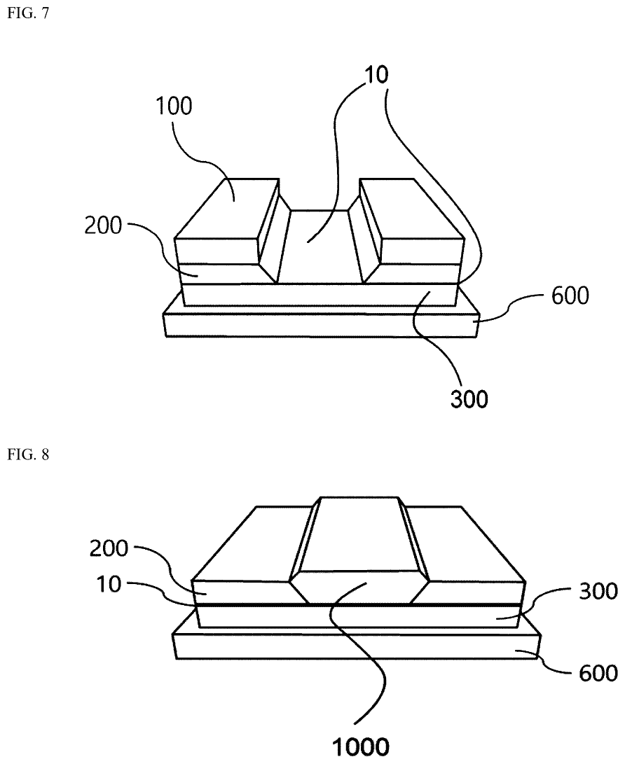

Next, referring to FIG. 8, an electrode layer 1000 is formed to make a planar contact with the conductive layer 10 exposed to the outside through the selective etching region. The electrode layer 1000 formed in this way has a large contact area with the conductive layer 10, resulting in a structure with lower contact resistance and higher transparency compared to the existing 1D edge contact.

The electrode layer 1000 may be formed using a metal material or a superconductor. Specifically, materials such as titanium (Ti) or aluminum (Al) may use electron beam evaporation, and materials such as niobium nitride (NbN), niobium (Nb), and molybdenum rhenium alloy (MoRe) may be deposited using DC sputtering, but are not limited thereto.

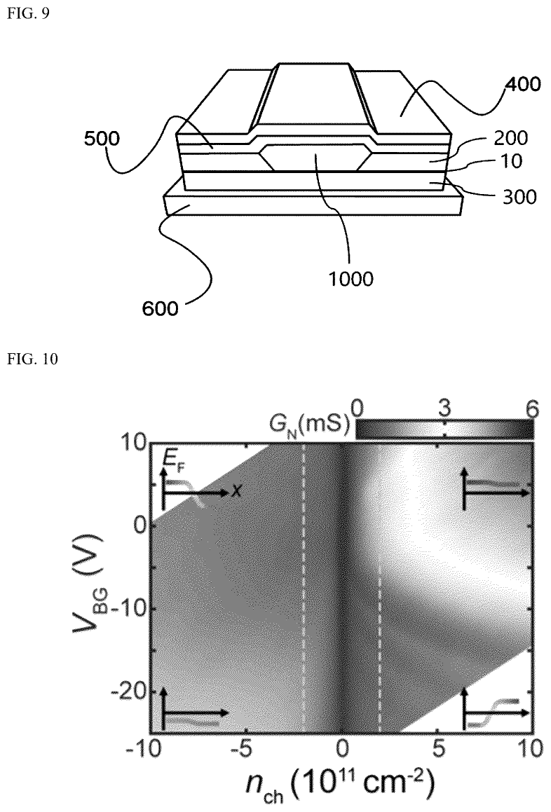

At this time, fluorine atoms remaining on the surface of the conductive layer 10 in the previous etching process serve to mitigate work function mismatch by canceling n-type doping occurring upon contact with the electrode layer 1000. Next, referring to FIG. 9, a gate insulating layer 500 is formed on the upper insulating layer 200 and the electrode layer 1000, and a second gate electrode 400 is formed thereon to complete the manufacture of the device.

The gate insulating layer 500 is for securing electrical insulation between the electrode layer 1000 and the second gate electrode 400, and may be formed by depositing a dielectric material such as aluminum oxide (Al₂O₃) to a thickness of about 30 nm to 40 nm (e.g., 32 nm) through an atomic layer deposition (ALD) process. This is effective in preventing leakage current by forming a uniform insulating film without pinholes.

Finally, a second gate electrode 400 is formed on the gate insulating layer 500. At this time, as shown in FIG. 9, when the substrate 600 is a highly doped silicon wafer, the substrate itself can serve as the lower first gate electrode 700, so a separate first gate electrode formation process may be omitted.

FIG. 10 is a graph showing conductance characteristics according to gate voltage of a device according to an embodiment of the present invention.

Referring to FIG. 10, the x-axis represents the charge density of the channel region (n_{ch}), and the y-axis represents the charge density of the junction region (n_{co}) controlled by the back gate voltage (V_{BG}). The brightness of the graph represents the normal state conductance (GN), and lighter gray or closer to white means higher conductance, and darker gray or closer to black means lower conductance.

As confirmed in the graph, in the first quadrant and the third quadrant where the polarities of the junction region (n_{co}) and the channel region (n_{ch}) are the same (n-n or p-p), a relatively bright shade appears indicating a high conductance value, whereas in the second quadrant and the fourth quadrant where the polarities are opposite to each other (n-p or p-n), a relatively dark shade appears indicating a low conductance value.

This means that when the polarities of the junction region and the channel region are matched by independently controlling the first and second gate electrodes, potential PN junction barriers formed at the contact interface can be eliminated.

Therefore, it can be seen that the dual gate structure of the present invention is beneficial for securing transparent contact characteristics in the entire bipolar operating environment.

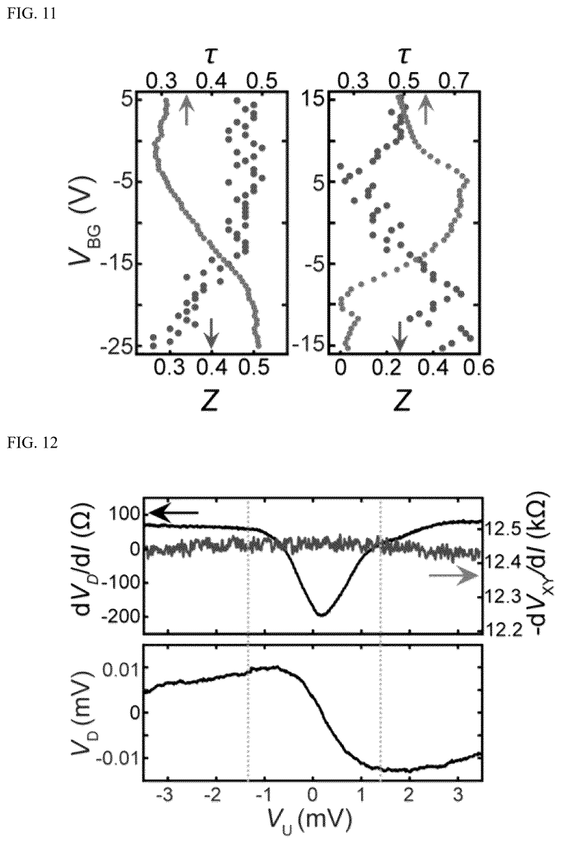

FIG. 11 is a graph showing a correlation between a contact barrier parameter (Z) and transparency (t) in a device according to an embodiment of the present invention.

This graph is extracted by fitting measured conductance data to the BTK (Blonder-Tinkham-Klapwijk) model, and the upper horizontal axis represents contact transparency (t, upper arrow direction), and the lower horizontal axis represents potential barrier strength (Barrier Strength, Z, lower arrow direction), respectively.

Referring to FIG. 11, it can be confirmed that the two parameters (Z, t) change showing an anticorrelation with each other according to the change of the back gate voltage (V_{BG}). Specifically, under an optimal voltage condition (e.g., around V_{BG} of about 10V in the right graph) where the charge density (n_{co}) of the junction region controlled by the first gate electrode is matched to have the same polarity as the charge density (n_{ch}) of the channel region, the barrier strength (Z) data indicated by the lower arrow decreases rapidly and shows a very low value of 0.3 or less (substantially close to 0). On the other hand, it can be seen that the contact transparency (τ) data indicated by the upper arrow moves to the right and reaches the maximum value under the same condition.

This shows that the high-pressure fluorine plasma etching and doping compensation mechanism according to the present invention minimizes interface defects between the electrode and the van der Waals material and realizes a transparent junction close to an ideal Ohmic contact.

FIG. 12 is a graph showing negative downstream resistance characteristics exhibited by a device according to an embodiment of the present invention in a quantum Hall state (v=−2).

The upper graph of FIG. 12 shows the downstream differential resistance (dV_{D}/dI), and the lower graph shows the downstream DC voltage (V_{D}), respectively.

Referring to the upper graph, it is confirmed that the downstream resistance (black solid line) indicated by the left arrow exhibits a distinct negative value of 0Ω or less in the voltage range inside the energy gap (A) of the superconducting electrode (area between two vertical dotted lines). For reference, the gray solid line indicated by the right arrow represents the Hall resistance.

Also, referring to the lower graph, it shows a negative slope in which the downstream voltage (V_{D}) responds with the opposite sign to the input voltage (Vu), which is decisive evidence that the Crossed Andreev Conversion phenomenon occurred efficiently.

That is, the device of the present invention experimentally shows that the superconducting proximity effect can be stably implemented even in the negative filling factor region (v<0), which was difficult to implement with existing technologies.

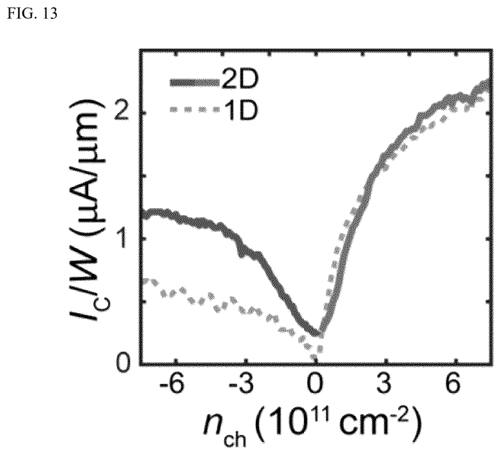

FIG. 13 is a graph comparing width-normalized critical currents (I_{C}/W) of an embodiment of the present invention (2D contact) and the prior art (1D contact).

Referring to FIG. 13, it can be seen that the 2D planar contact device according to the present invention indicated by a solid line shows generally superior characteristics compared to the conventional 1D edge contact device indicated by a dotted line. It can be confirmed that the 2D planar contact device (solid line) according to the present invention exhibits a critical current density about twice as high as that of the conventional 1D edge contact device (dotted line) under the same charge density (n_{ch}) condition.

Specifically, while the conventional 1D contact structure has low current injection efficiency due to limited contact area and large work function difference, the 2D contact structure of the present invention shows that the work function difference is minimized by the fluorination compensation effect and the contact area is wide, so that the superconducting proximity effect efficiency is dramatically improved.

The description of the present specification described above is for illustrative purposes, and those of ordinary skill in the art will readily appreciate that aspects of the present specification can easily be modified into other specific forms without changing the technical idea or essential features described in this specification. Therefore, it should be understood that the embodiments described above are illustrative in all respects and not restrictive. For example, each component described as a single type may be implemented in a distributed form, and likewise components described as distributed may be implemented in a combined form.

The scope of the present specification is indicated by the following claims, and all changes or modifications derived from the meaning and scope of the claims and their equivalents should be construed as being included in the scope of the present specification.

1. A device including a two-dimensional junction between a van der Waals material and an electrode, the device comprising:
a lower insulating layer made of an insulating 2D material;
a conductive layer stacked on the lower insulating layer by interlayer van der Waals bonding and made of a conductive 2D material;
an upper insulating layer stacked on the conductive layer by interlayer van der Waals bonding, made of an insulating 2D material, and having a selective etching region formed therein;
an electrode layer formed in the selective etching region to form a planar contact with the conductive layer;
a gate insulating layer formed on the upper insulating layer and the electrode layer; and
first and second gate electrodes located on the gate insulating layer, under the lower insulating layer, or both, and applying a gate electric field to at least a partial region of the conductive layer.

2. The device of claim 1, wherein the conductive layer includes a junction region forming a planar contact with the electrode layer and a channel region encapsulated by the upper insulating layer and the lower insulating layer, and
wherein charge density and polarity of the junction region are controlled by electric field application through the first gate electrode, and charge density and polarity of the channel region are controlled by electric field application through the first and second gate electrodes.

3. The device of claim 1, wherein the first gate electrode is located under the lower insulating layer, and the second gate electrode is located on the electrode layer, and
wherein the gate insulating layer is interposed between the electrode layer and the second gate electrode. wherein the gate insulating layer is interposed between the electrode layer and the second gate electrode.

4. The device of claim 1, wherein the electrode layer includes one or more superconductors selected from the group consisting of niobium (Nb), niobium nitride (NbN), titanium (Ti), niobium titanium nitride (NbTiN), molybdenum rhenium alloy (MoRe), tantalum (Ta), aluminum (Al), vanadium (V), lead (Pb), and indium (In).

5. The device of claim 1, wherein the device is any one of a semiconductor device, a superconducting qubit, a quantum Hall device, and a superconducting Josephson junction device. The device of claim 1, wherein the device is any one of a semiconductor device, a superconducting qubit, a quantum Hall device, and a superconducting Josephson junction device.

6. The device of claim 5, wherein the device is a quantum Hall device, and wherein in a state where a filling factor of the channel region, which is the conductive layer, is controlled to be a negative value (v<0) through the first and second gate electrodes, Crossed Andreev Conversion occurs at an interface between the electrode layer and the channel region to exhibit a negative downstream resistance.

7. The device of claim 1, wherein a surface of the conductive layer corresponding to the selective etching region is p-doped by fluorine (F) atoms, and the p-type doping compensates for n-type doping induced by contact with the electrode layer, thereby reducing a work function difference (ΔW) between the conductive layer and the electrode layer.

8. The device of claim 2, wherein when a charge density (n_{co}) of the junction region controlled by the first gate electrode is matched to have the same polarity as a charge density (n_{ch}) of the channel region, a potential barrier strength (Z) at an interface between the junction region and the channel region is 0.3 or less based on a Blonder-Tinkham-Klapwijk (BTK) model.

9. A method of manufacturing a device including a two-dimensional junction between a van der Waals material and an electrode, the method comprising:
sequentially stacking a lower insulating layer made of an insulating 2D material, a conductive layer made of a conductive 2D material, and an upper insulating layer made of an insulating 2D material, such that the lower insulating layer, the conductive layer, and the upper insulating layer are interlayer-bonded by van der Waals force;
forming a selective etching region in the upper insulating layer to expose a part of the conductive layer;
forming an electrode layer to form a planar contact with the exposed conductive layer;
forming a gate insulating layer on the upper insulating layer and the electrode layer; and
forming first and second gate electrodes on the gate insulating layer, under the lower insulating layer, or both to apply a gate electric field to at least a partial region of the conductive layer.

10. The method of claim 9, wherein the conductive layer includes a junction region forming a planar contact with the electrode layer and a channel region encapsulated by the upper insulating layer and the lower insulating layer, and
wherein charge density and polarity of the junction region are controlled by electric field application through the first gate electrode, and charge density and polarity of the channel region are controlled by electric field application through the first and second gate electrodes.

11. The method of claim 9, wherein the first gate electrode is formed under the lower insulating layer, and the second gate electrode is formed on the gate insulating layer.

12. The method of claim 9, wherein in the step of forming the selective etching region, a fluorine-based gas plasma is applied under conditions of a pressure of 150 mTorr to 500 mTorr and an RF power of 30 W or less.

13. The method of claim 12, wherein the fluorine-based gas includes carbon tetrafluoride (CF4), the pressure is 200 mTorr to 300 mTorr, and the RF power is 5 W to 15 W.

14. The method of claim 9, wherein the step of forming the selective etching region includes a step in which fluorine (F) atoms derived from an etching gas remain on a surface of the exposed conductive layer to induce p-type doping, thereby compensating for n-type doping occurring during formation of the electrode layer to reduce a work function difference between the conductive layer and the electrode layer.

15. The method of claim 9, wherein the step of forming the electrode layer controls interface characteristics between a metal and the conductive layer such that a potential barrier parameter (Z) at an interface with the conductive layer is 0.3 or less, thereby allowing the completed device to exhibit Crossed Andreev Conversion characteristics in a negative filling factor region.
